(19) United States
(12) Patent Application Publication
(10) Pub. No.: US 2014/0305492 A1
(43) Pub. Date: Oct. 16, 2014

(54) SOLAR MODULE WITH REDUCED POWER LOSS AND PROCESS FOR THE PRODUCTION THEREOF

(71) Applicants: Arnaud Verger, Paris (FR); Fabien Lienhart, Paris (FR); Paul Mogensen, Torgau (DE); Walter Stetter, Illertissen (DE); Alejandro Avellan, Muenchen (DE)

(72) Inventors: Arnaud Verger, Paris (FR); Fabien Lienhart, Paris (FR); Paul Mogensen, Torgau (DE); Walter Stetter, Illertissen (DE); Alejandro Avellan, Muenchen (DE)

(73) Assignee: SAINT-GOBAIN GLASS FRANCE

(21) Appl. No.: 14/235,960

(22) PCT Filed: Aug. 1, 2012
(86) PCT No.: PCT/EP2012/064998

§ 371 Date: Apr. 2, 2014

(30) Foreign Application Priority Data
Aug. 10, 2011 (EP) 11177057.4

(51) Int. Cl. H01L 31/048; H01L 31/18

(52) U.S. Cl. CPC H01L 31/048; H01L 31/1876
USPC 136/251; 438/67

(57) ABSTRACT

A solar module is described. The solar module has a laminated composite of two substrates bonded to one another by at least one bonding layer, between which substrates there are solar cells which are connected in series and which each have an absorber zone made of a semiconducting material between a front electrode arranged on a light entrance side of the absorber zone and a rear electrode. A diffusion barrier differing from the front electrode is located between each absorber zone and the bonding layer and is designed to inhibit the diffusion of water molecules from the bonding layer into the absorber zone and/or the diffusion of dopant ions from the absorber zone into the bonding layer. A process for producing such a solar module is also described.

The invention is in the technical area of photovoltaic energy generation and relates to a solar module with reduced power loss due to aging and a method for the production thereof, as well as the use of a difusion barrier in such a solar module.

Photovoltaic layer systems for the direct conversion of sunlight into electrical energy are well known. They are commonly referred to as “solar cells”. The term “thin-film solar cells” refers to layer systems with small thicknesses of only a few microns that require carrier substrates for adequate mechanical stability. Known carrier substrates include inorganic glass, plastics (polymers), or metals, in particular metal alloys, and can, depending on the respective layer thickness and the specific material properties, be designed as gi plates or flexible films.

In view of the technological handling quality and level of efficiency, thin-film solar cells with a semiconductor layer of amorphous, micromorphous, or polycrystalline silicon, cadmium telluride (CdTe), gallium arsenide (GaAs), or a chalcopyrite compound, in particular copper-indium/gallium-sulfur/selenium, abbreviated by the formula Cu(In,Ga)(S,Se)₂, have proved advantageous, with, in particular, copper-indium-diselenide (CuInSe₂ or CIS) distinguished by a particularly high absorption coefficient due to its band gap adapted to the spectrum of sunlight.

In order to obtain a technically useful output voltage, many solar cells are serially connected to one another, with thin-film solar modules offering the advantage of a large-area arrangements of (monolithically) integratedly connected thin-film solar cells. The series connection of thin-film solar cells has already been described many times in the patent literature. Reference is made merely by way of example to the printed publication DE4324318 C1.

As a rule, to produce thin-film solar cells, the layers are applied directly on the carrier substrate, which is, for its part, bonded to a front transparent cover layer by an adhesion-promoting adhesive film to form a weather-resistant photovoltaic or solar module. This procedure is referred to as “lamination”. Low-iron soda lime glass, for example, is selected for the material of the cover layer. The adhesion-promoting polymer film is made, for example, of ethylene vinyl acetate (EVA), polyvinyl butyral (PVB), polyethylene (PE), polyethylene acyl copolymer, or polyacrylamide (PA). Increasingly, in recent years, PVB adhesive films, have been used in thin-film solar modules with laminated sheet structure.

With laminated thin-film solar modules, an age-induced continuous increase in the series resistance can be observed, which, after service lives of multiple thousands of operating hours gradually transitions into an at least approx. constant value. This aging results in an undesirable degradation of the level of efficiency of the solar module.

In contrast, the object of the present invention consists in making available a solar module with a reduced age-induced power loss. This and other objects are accomplished according to the proposal of the invention by a solar module, a method for production thereof, as well as the use of a diffusion barrier in such solar module with the characteristics of the coordinated claims. Advantageous embodiments of the invention are indicated by the characteristics of the subclaims.

According to the invention, a solar module, in particular a thin-film solar module is presented. The solar module comprises a laminated composite of two substrates bonded to each other by at least one (plastic) adhesive layer between which substrates are situated solar cells, preferably serially connected to each other in integrated form, in particular thin-film solar cells. The solar cells arranged between the two substrates are produced by structuring a layer structure. Thus, the solar cells have in each case an absorber zone, made of a semiconducting material, which is situated between a front electrode arranged on the light-entry side of the absorber zone and a rear electrode. Preferably, the semiconductor material consists of a chalcopyrite compound which can, in particular, be a I-III-VI-semiconductor from the group copper indium/gallium disulfur/diselenide (Cu(In,Ga)(S,Se)₂) for example, copper indium diselenide (CuInSe₂ or CIS) or related compounds. The semiconductor material is customarily doped with dopant ions, for example, sodium ions.

Preferably, a rear-side carrier substrate is adhesively bonded by means of an adhesive layer, for example, PVB, to a front-side cover layer as transparent as possible to electromagnetic radiation in the absorber range of the semiconductor (e.g., sunlight), for example, glass plate, with the solar cells arranged on the carrier substrate embedded in the adhesive layer.

It is essential here that, between the absorber zone of each solar cell and the adhesive layer, a diffusion barrier (barrier layer) be situated, which is implemented so as to inhibit the diffusion of water molecules out of the adhesive layer into the absorber zone and/or the diffusion of dopant ions out of the absorber zone into the adhesive layer. The material of the diffusion barrier is different from the material of the front electrode. The diffusion harrier has, for this purpose, such a layer thickness or a suitable layer thickness such that the diffusion of water molecules and/or dopant ions can be inhibited. The layer thickness depends on the respective material of the diffusion barrier.

Without being restricted to one theory, it is assumed that a substantial cause of the increase in the series resistance of the connected solar cells described in the introduction is a diffusion of water molecules out of the adhesive layer into the semiconductor material of the solar cells and/or a diffusion of dopant ions out of the absorber zone into the adhesive layer. The diffusive transport of water molecules and dopant ions results in a change in the electrical properties of the semiconductor material, since, on the one hand, dopant ions migrate out of the semiconductor material and, on the other, water molecules bond to the dopant ions in the semiconductor material. For example, PVB has a water fraction in the single-digit per thousand range, which is, nevertheless, deemed adequate to have an undesirable effect with regard to the power loss. The applicant thus discerned for the first time that the power loss observed with aging in solar modules is based on a change in the electrical properties of the semiconductor material of the solar cell due to the diffuse transport of water molecules and/or dopant ions. By means of the diffusion barriers between the adhesive layer and the absorber zones, a diffuse transport of water molecules and/or dopant ions can be at least largely, in particular, completely, prevented such that the power loss of solar modules associated with aging can be reliably and certainly reduced.

In order to at least not substantially negatively affect the power of the solar module by the diffusion barriers of the solar cells, the material of the diffusion barriers must be selected such that it is permeable (transparent) to electromagnetic radiation in the absorption range of the solar cells (e.g. sunlight). The term “permeable” refers here to transmission for the wavelength range in question, i.e., the absorption range of the semiconductor (in the case of CIGS 380 nm to 130 nm), which is at least greater than 70%, preferably greater than 80%, and in particular preferably greater than 90%.

In the solar module according to the invention, the material and the layer thickness of the diffusion barriers of the solar cells can, in principle, be freely selected as long as it is guaranteed that the diffusion of water molecules and/or dopant ions can be inhibited and, in particular, at least virtually completely prevented. It can, in general, be an organic or inorganic material. Preferably, the material of the diffusion barriers is an inorganic material which affords the process-technology advantage of good workability, since deposition from the gas phase by means of methods known per se such as chemical vapor deposition (CVD) or physical vapor deposition (PVD) or sputtering processes is possible. In contrast to this, organic materials typically require wet-chemical deposition, which is more difficult to integrate into the process sequence for production of solar modules and is fraught with process-technology disadvantages.

Preferably, the inorganic material of the diffusion barriers of the solar cells is at least one metal oxide. As experiments by the applicant have demonstrated, by means of metal oxides, a diffuse transport of water molecules and dopant ions can be particularly effectively prevented.

Advantageously, the diffusion barriers comprise, in each case, an alternating sequence of at least one metal oxide layer and at least one metal nitride layer, for example, an alternating sequence of at least one layer made of tin zinc oxide and at least one layer made of silicon nitride. As experiments by the applicant have demonstrated, diffusive transport of water molecules and dopant ions can be particularly effectively prevented by means of the alternating sequence of varied materials, which is always associated with different grain growth. On the other hand, metal oxides and metal nitrides are characterized by very good workability, with layers thereof depositable from the gas phase or by means of a sputtering process such that the production of the diffusion barriers can be integrated relatively simply and economically into the production of solar modules. Moreover, such diffusion barriers have excellent transparency to electromagnetic radiation (e.g., light) in the absorption range of semiconductor materials preferred according to the invention, which are based, for example, on a chalcopyrite compound.

For the property as a barrier to inhibit or prevent diffusive transport of water molecules and dopant ions, the layer thickness of the diffusion barriers must be taken into account as a function of the material selected. As experiments by the applicant have demonstrated, with the use of a metal oxide as the material for the diffusion barriers, virtually no diffusion inhibiting effect can be detected with layer thicknesses up to ca. 50 nm. Preferably, the layer thickness of a diffusion barrier made of a metal oxide is more than 50 nm, in particular more than 100 nm.

Since the permeability of the diffusion barriers for electromagnetic radiation increases with increasing layer thickness, the lowest possible layer thickness with equally good effect as a barrier for diffuse transport of water molecules and dopant ions is, on the other hand, advantageous. Preferably, the layer thickness of the diffusion barrier is in the range of more than 50 nm to 200 nm, in particular in the range above 100 nm to 200 nm. As experiments by the applicant with metal oxides have surprisingly demonstrated, at least with some materials, virtually no additional effect with regard to the action as a barrier for diffuse transport of water molecules and dopant science can be obtained with a further increase of layer thickness beyond 100 nm. Consequently, it can be advantageous for the layer thickness of the diffusion barrier to be in the range of more than 50 nm to 100 nm, in particular in the range of more than 50 nm to less than 100 nm, in particular in the range from 75 nm to 100 nm, in particular in the range from 75 nm to less than 100 nm.

In the solar module according to the invention, the diffusion barriers are situated between the absorber zones and the adhesive layer. For example, the diffusion barriers are, for this purpose, arranged between the front electrodes and the absorber zones. In an embodiment advantageous from the standpoint of the electrical properties in the front electrode/absorber zone transition region of the solar cells, the diffusion barriers are arranged between the front electrodes and the adhesive layer.

In a typical production method for solar cells, in particular thin-film solar cells, the rear electrodes are produced by forming first layer trenches in a rear electrode layer, the absorber zones by forming a second layer trenches in a semiconductor layer, and the front electrodes by forming third layer trenches in a front electrode layer. Here, it is, in principle, possible for the material of the diffusion barriers to be situated inside the last formed third layer trenches for the structuring of the front electrodes, with the optically active regions of the solar module, i.e., the absorber zones, completely separated from the adhesive layer by the diffusion barriers. In an alternative embodiment, no material of the diffusion barriers is situated inside the third layer trenches, in other words, the third layer trenches are free of the material of the diffusion barriers. Such a solar module comprises a rear electrode layer with first layer trenches for forming the rear electrodes, a semiconductor layer with second layer trenches for forming the absorber zones, a front electrode layer with third layer trenches for forming the front electrodes, with the diffusion barriers of the solar cells situated outside the third layer trenches.

This measure brings with it the process-technology advantage that a barrier layer for producing the diffusion barriers can be deposited even before the incorporation of the third layer trenches for forming the front electrodes, for example, on the front electrode layer. Thus, it is possible to dispense with another coating system for application of the barrier layer, which is associated with significant cost savings in the production of the solar modules. As experiments by the applicant have demonstrated, the diffuse transport of water molecules and dopant ions allowed between the adhesive layer and the absorber zone is negligibly little in the region of the third layer trenches such that virtually no increase in series resistance occurs.

The invention further extends to a method for producing a solar module as described above, in particular a thin-film solar module, which includes a step wherein diffusion barriers different from the front electrode are arranged between the absorber zones and the adhesive layer.

In an advantageous embodiment of the method, a barrier layer for the formation of the diffusion barriers is produced by chemical or physical vapor deposition or sputtering, by which means an economical integration, simple in terms of process technology, of the production of the diffusion barriers into the production of the solar module is enabled.

In principle, the diffusion barriers can be produced in each case as an individual layer or by deposition of a plurality of layers made of at least two different materials. In an advantageous embodiment of the method, the barrier layer for the formation of the diffusion barriers is produced by deposition of at least one metal oxide layer. Advantageously, the barrier layer is produced by deposition of an alternating sequence of at least one metal oxide layer and at least one metal nitride layer.

In an advantageous embodiment of the method, the rear electrodes are produced by forming first layer trenches in a rear electrode layer; the absorber zones, by forming second layer trenches in a semiconductor layer; and the front electrodes, by forming third layer trenches in a front electrode layer, with the barrier layer serving to produce the diffusion barriers being deposited on the front electrode layer serving to produce the front electrodes. Alternatively, it would also be possible for the barrier layer to be deposited on the front electrodes and the third layer trenches separating the front electrodes from one another.

It should be noted merely for completeness that in the context of the present invention, the diffusion barriers situated between the absorber zones of the solar cells and the adhesive layer can be layer sections separated from one another, which are produced, for example, by structuring the barrier layer. It is, however, equally possible for the diffusion barriers to be layer sections of one contiguous barrier layer.

The invention also extends to the use of a diffusion barrier as described above in a solar module as described above. The solar module comprises a laminated composite of two substrates bonded to one another by at least one adhesive layer, between which substrates are situated serially connected solar cells, which have in each case an absorber zone, made of a semiconducting material, between a front electrode arranged on a light-entry side of the absorber zone and a rear electrode, wherein the diffusion barrier is different from the front electrode and is situated between the absorber zone and the adhesive layer, wherein the diffusion barrier is implemented to inhibit the diffusion of water molecules out of the adhesive layer into the absorber zone and/or the diffusion of dopant ions out of the absorber zone into the adhesive layer. The use according to the invention extends to all above-described embodiments of the diffusion barrier as well as to all above-described embodiments of the solar module, with reference made to the statements regarding them to avoid repetitions.

### BRIEF DESCRIPTION OF THE DRAWINGS

The invention is now explained in detail using exemplary embodiments, with reference to the accompanying figures. They depict, in simplified, not-to-scale representation:

FIG. 1 a schematic representation of an exemplary thin-film solar module;

FIG. 2-3 diagrams to illustrate the action of various diffusion barriers.

### DETAILED DESCRIPTION OF THE DRAWINGS

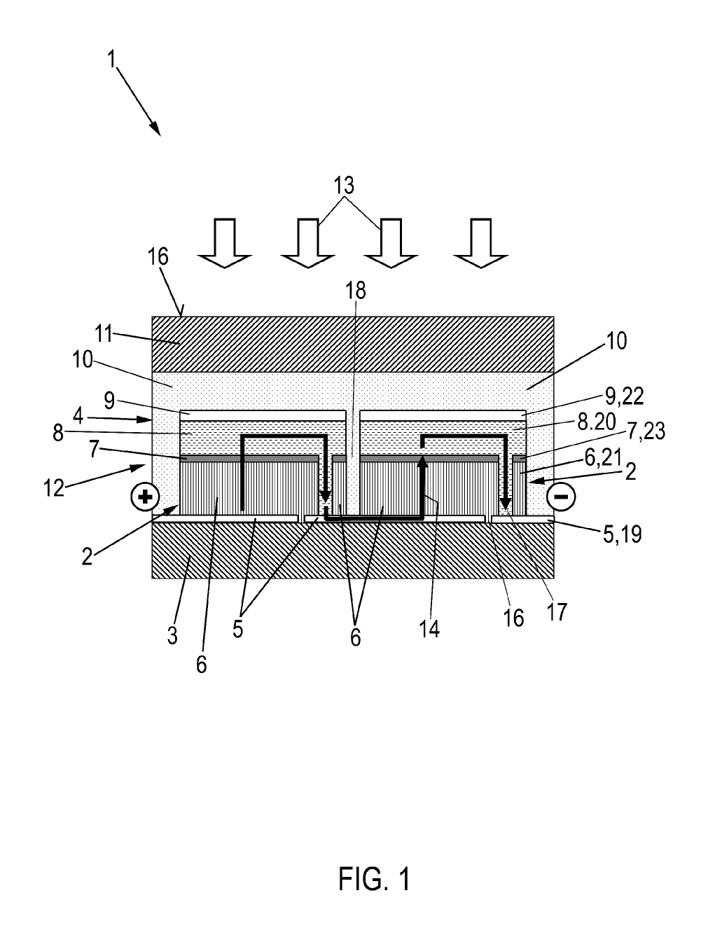

FIG. 1 schematically illustrates a thin-film solar module identified as a whole by the reference character 1. The thin-film solar module 1 comprises a plurality of thin-film solar cells 2 serially connected to one another in an integrated form, with, for the purpose of a simpler representation, only two thin-film solar cells 2 depicted in FIG. 1. It is understood that a large number (for example, ca. 100) of thin-film solar cells 2 are serially connected in the thin-film solar module 1.

The thin-film solar module 1 has a laminated sheet structure, in other words, it has an electrically insulating first (carrier) substrate 3 with a layer structure 4 of thin layers applied thereupon, which is arranged on a light-entry-side surface of the first substrate 3. The electromagnetic radiation 13, for example, sunlight, incident on the thin-film solar cells 2 for the purpose of photovoltaic current generation, is illustrated by arrows. The layer structure 4 can be produced by vapor deposition, i.e., chemical deposition (CVD) or physical deposition (PVD) from the gas phase, or by sputtering (magnetic field assisted cathode sputtering). The first substrate 3 is implemented here, for example, as a rigid glass plate with relatively low light permeability, with it equally possible to use other electrically insulating materials with the desired strength and inert behavior relative to the process steps performed.

Each thin-film solar cell 2 has a rear electrode 5 arranged on the light-entry-side surface of the first substrate 3, a photovoltaically active semiconductor or absorber zone 6 arranged on the rear electrode 5, a buffer zone 7 arranged on the semiconductor zone 6, as well as a front electrode 8 arranged on the buffer zone 7. A heterojunction, i.e., a sequence of layers of the opposing conductor type, is formed by the front electrode 8 together with the buffer zone 7 and the absorber zone 6. The buffer zone 7 can effect an electronic adaptation between the semiconducting material of the absorber zone 6 and the material of the front electrode 8. Moreover, a diffusion barrier 9 is arranged on the front electrode 8, by means of which diffuse transport of water molecules and dopant ions (e.g., sodium ions) can be at least almost completely, in particular completely, prevented.

To form the thin-film solar cells 2 serially connected to one another in integrated form, the various layers of the layer structure 4 are structured on the first substrate 3 using a suitable structuring technology such as laser writing and machining, for example, drossing or scratching. It is important here that the losses of photoactive area be as low as possible and that the structuring technology used be selective for the material to be removed. Typically, for each thin-film solar cell 2, such structuring includes three structuring steps, that are abbreviated as P1, P2, P3.

First, a rear electrode layer 19, made, for example, of an opaque metal such as molybdenum (Mo), is applied on the first substrate 3. The rear electrodes layer 19 has a layer thickness, that is, for example, in the range from 300 nm to 600 nm and is, in particular, ca. 500 nm.

In a first structuring step P1, the rear electrode layer 19 is interrupted by creation of first layer trenches 16, by means of which the rear electrodes 5 are formed.

Next, a semiconductor layer 21 is deposited on the rear electrodes 5 and the first layer trenches 16 separating the rear electrodes 5 from one another. The semiconductor layer 21 consists of a semiconductor doped with dopant ions (metal ions), whose band gap is preferably capable of absorbing the greatest possible fraction of the sunlight. The semiconductor layer 21 consists, for example, of a p-conductive chalcopyrite semiconductor, for example, a compound from the group Cu(In,Ga)(S,Se)₂, in particular sodium (Na)-doped Cu(In,Ga)(S,Se)₂. The semiconductor layer 21 has a layer thickness that is, for example, in the range from 1-5 μm and is, in particular, ca. 2 μm. The first layer trenches 16 are filled with the semiconductor material during the application of the semiconductor layer 21. Then, a buffer layer 23 is deposited on the semiconductor layer 21. The buffer layer 23 consists here, for example, of a single layer of cadmium sulfide (CdS) and a single layer of intrinsic zinc oxide (i-ZnO), not shown in detail in FIG. 1.

Next, in a second structuring step P2, the two semiconductor layers, namely the semiconductor layer 21 and the buffer layer 23, are interrupted by creation of second layer trenches 17, by means of which the semiconductor zones 6 and the buffer zones 7 are formed.

After that, a front electrode layer 20 is deposited on the buffer zones 7 and the second layer trenches 17 that separate the buffer zones 7 and semiconductor zones 6 from one another. The material of the front electrode layer 20 is transparent to radiation in the absorption range of the semiconductor layer 21, e.g., in the visual spectral range, such that the incident electromagnetic radiation 13 is only slightly weakened. The front electrode layer 20 is based, for example, on a doped metal oxide, for example, n-conductive aluminum (Al)-doped zinc oxide (ZnO). Such a front electrode layer 20 is, in general, referred to as a TCO-layer (TCO=transparent conductive oxide). The layer thickness of the front electrode layer 20 is, for example, ca. 500 nm. The second layer trenches 16 are filled with the electrically conductive material of this layer during the application of the front electrode layer 20.

Next, a barrier layer 22 is deposited, for example, by vapor deposition or sputtering, on the front electrode layer 20. The barrier layer 22 is preferably made of an inorganic material, in particular of at least one layer of metal oxide, preferably an alternating sequence of metal oxide layers and metal nitride layers, for example, made of at least one tin zinc oxide layer and at least one silicon nitride layer. The layer thickness of the barrier layer 22 is preferably greater than 50 nm and is here, for example, in the range from more than 50 nm to 200 nm, in particular in the range from 75 nm to 100 nm, in particular in the range from 75 nm to less than 100 nm. Alternatively, it would also be possible for the barrier layer 22 to be arranged between the front electrode layer 20 and the semiconductor layer 21.

In a third structuring step P3, the barrier layer 22 and the front electrode layer 20 are interrupted by the creation of third layer trenches 18, by means of which the front electrodes 8 and the diffusion barriers 9 are formed. Alternatively, it would be conceivable for the third layer trenches 18 to extend downward all the way to the first substrate 3.

A conversion of the various metals to form semiconductor material takes place through heating in a furnace (RTP=rapid thermal processing), which is known per se to the person skilled in the art, such that it need not be discussed in detail here.

In the example depicted here, both the resultant positive voltage terminal (+) and the resultant negative voltage terminal (−) of the thin-film solar modules 1 are guided over the rear electrodes 5 and are electrically contacted there. Through illumination of the thin-film solar cells 2, an electrical voltage is created on the two voltage terminals. A resulting current path 14 is illustrated by arrows in FIG. 1.

For protection against environmental influences, the first substrate 3 with the thin-film solar cells 2 applied thereupon is bonded to a second substrate 11 to form a weather-resistant composite. For this purpose, a (plastic) adhesive layer 10 is applied on the front electrodes 8 and the third layer trenches 18 separating the front electrode 8 from one another, which adhesive layer serves to encapsulate the layer structures 4. The third layer trenches 18 are filled by the insulating material of this layer during application of the adhesive layer 10.

The second substrate 11 is implemented as a front-side cover layer transparent to the radiation 13 and, for example, in the form of a glass plate of extra white glass with low iron content, with it equally possible to use other electrically insulating materials with desired strength and inert behavior relative to the process steps performed. The second substrate 11 serves for the sealing and mechanical protection of the layer structure 4. The thin-film solar module 1 can be illuminated via a front-side module surface 15 to generate electrical energy.

The two substrates 3, 11 are fixedly bonded to one another by the adhesive layer 10 (“laminated”), with the adhesive layer 10 implemented here, for example, as a thermoplastic adhesive layer, that becomes plastically deformable through heating and, upon cooling, fixedly bonds the two substrates 3 and 11 to one another. The adhesive layer 10 consists here, for example, of PVB. The two substrates 3, 11 with the thin-film solar cells 2 embedded in the adhesive layer 10 together form a laminated composite 12. Water with a weight fraction in the single-digit per thousand range is contained in the adhesive layer 10 consisting here, for example, of PVB. A diffusive transport of water molecules out of the adhesive layer 10 into the absorber zones 6 can be at least largely prevented by the diffusion barriers 9. It is equally possible for diffusion of the dopant ions (here, e.g., sodium ions) out of the absorber zones 6 into the adhesive layer 10 to be at least largely prevented by the diffusion barriers 9. By this means, a power loss of the thin-film solar module 1 can be reduced. To be sure, diffusive transport of water molecules and dopant ions can occur in the region of the third layer trenches 18; however, this is deemed negligible.

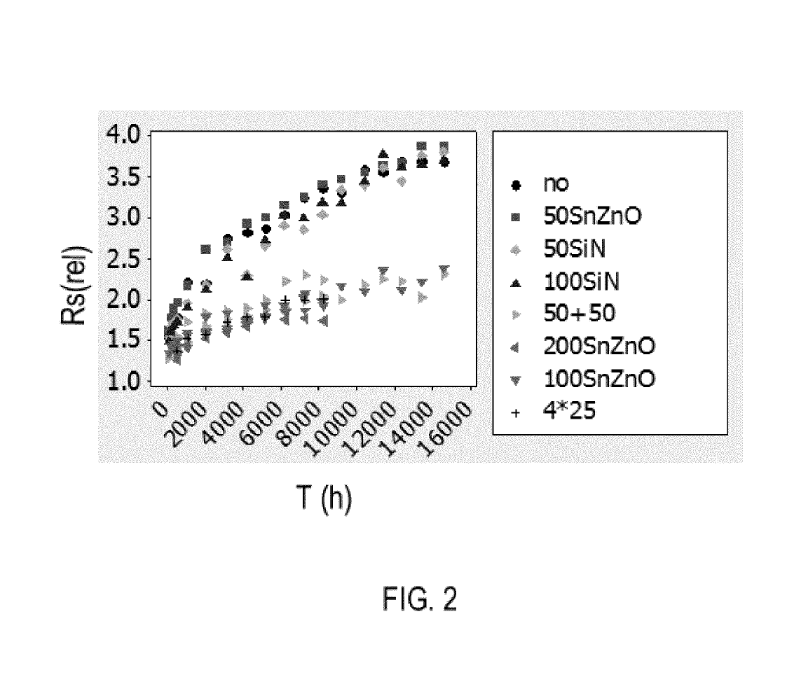

FIG. 2 indicates, using a schematic measurement diagram for the thin-film solar module 1 illustrated in FIG. 1, the relative electrical series resistance Rs(rel) of the connected thin-film solar cells 2, based on the series resistance at the time of initial operation (T=0), as a function of the operating time or service life T (h) in hours, for various diffusion barriers 9. In the thin-film solar module 1, two glass substrates 3, 11 were laminated with PVB as the adhesive layer 10. The absorber zones 6 consist of a p-conductive chalcopyrite semiconductor, in this case, for example, sodium (Na)-doped Cu(In,Ga) (S,Se)₂.

For the measurement, the thin-film solar module 1 was subjected to accelerated aging by heating to approx. 85° C. in a dry environment.

The measurement curves correspond to various thin-film solar modules 1, wherein, in each case, only the diffusion barriers 9 were changed. In detail, the following measurement curves were determined for a thin-film solar module 1:

Measurement curve (1): a diffusion barrier made of SnZnO with a layer thickness of 50 nm (50SnZnO)

Measurement curve (2): a diffusion barrier made of SiN with a layer thickness of 50 nm (50SiN)

Measurement curve (3): a diffusion barrier made of SiN with a layer thickness of 100 nm (100SiN)

Measurement curve (4): a diffusion barrier made of a SnZnO layer with a layer thickness of 50 nm and a SiN layer with a layer thickness of 50 nm (50+50)

Measurement curve (5): a diffusion barrier made of SnZnO with a layer thickness of 200 nm (200SnZnO)

Measurement curve (6): a diffusion barrier made of SnZnO with a layer thickness of 100 nm (100SnZnO)

Measurement curve (7): a diffusion barrier made of four layers, wherein SnZnO layers and SiN layers are arranged in an alternating sequence and the layers have, in each case, a layer thickness of 25 nm (4*25)

Also measured as a reference was:

Measurement curve (0): thin-film solar module 1 without diffusion barrier (no)

From measurement curve (0), it can be seen that the relative series resistance of the thin-film solar module 1 increases continuously due to aging, with saturation behavior discernible. After ca. 14000 hours of service life, the series resistance virtually stops increasing. Assumed as the cause for this is the inward diffusion of water molecules out of the PVB adhesive layer 10 into the absorber zones 6 as well as the outward diffusion of sodium ions out of the absorber zones 6 into the adhesive layer 10. During the aging, the series resistance increases to 3.5 to 4 times its starting value at the time of initial operation of the thin-film solar module 1.

The measuring points of the measurement curves (1) to (3) are relatively close to each other and differ at least insignificantly from the measuring points of the reference measurement curve (0). It follows that 50-nm-thick diffusion barriers made of SnZnO have essentially no effect relative to a reduction of the increase in the series resistance of the thin-film solar module 1. The same holds for 50-nm-thick diffusion barriers made of SiN as well as for 100-nm-thick diffusion barriers made of SiN.

In contrast to this, in the measurement curves (4) to (7), a clear effect relative to a reduction of the increase in the series resistance of the thin-film solar module is discernible. Thus, by means of 100-nm-thick diffusion barriers, consisting, in each case, of a 50-nm-thick SnZnO layer and a 50-nm-thick SiN layer, 100-nm-thick or 200-nm-thick diffusion barrier made of SnZnO, as well as by means of 100-nm-thick diffusion barriers, consisting, in each case, of four 25-nm-thick SnZnO layers and SiN layers in alternating sequence, the increase in the series resistance can be significantly reduced.

The measure curves (4) to (7) are relatively close to each other and differ at least insignificantly from each other. During the aging, the series resistance increases only to ca. 2 to 2.5 times its starting value at the time of initial operation of the thin-film solar module 1 such that a ca. 50% reduction of the increase in series resistance is obtainable by means of such diffusion barriers. Assumed as a cause for this is an inhibition of the diffuse transport of water molecules and sodium ions through the diffusion barriers of the solar cells.

Thus, with diffusion barriers made of SnZnO, a good diffusion-inhibiting effect can be reached only above a layer thickness of 50 nm, in particular with a layer thickness of 100 nm and 200 nm, with virtually no further difference discernible with regard to a layer thickness of 100 nm or 200 nm. A correspondingly good effect is also discernible for those diffusion barriers in which SnZnO and SiN are contained in combination, where, with a total layer thickness of 100 nm for the diffusion barriers, a 50-nm-thick SnZnO layer or two 25-nm-thick SnZnO layers suffice to obtain a good diffusion-inhibiting effect. By means of a division of the diffusion barriers into a plurality of layers with an alternating material sequence, a particularly good diffusion-inhibiting effect can be obtained.

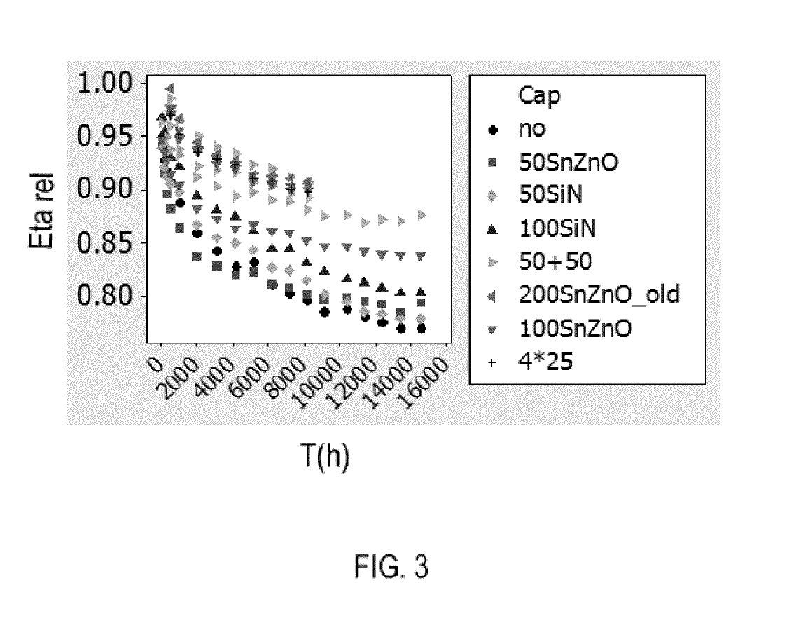

FIG. 3 indicates, for the measurement curves (0) to (7), in each case, the relative level of efficiency Eta(rel) of the thin-film solar module 1, based on the level of efficiency of the thin-film solar module 1 at the time of initial operation (T=0), as a function of the operating time or service life T(h) in hours.

Accordingly, it can be discerned that the level of efficiency is reduced through aging by ca. 20 to 25%. The same holds for 50-nm-thick diffusion barriers made of SnZnO or SiN. A relatively lower effect is observable for 100-nm-thick diffusion barriers made of SiN, where the level of efficiency is reduced by ca. 18%. With diffusion barriers made of 100-nm-thick SnZnO, a reduction of the level of efficiency by ca. 13% can be achieved. Best results are obtained for the diffusion barriers of the measurement curves (4) to (7), where the level of efficiency of the thin-film solar module is reduced by only ca. 10%. Thus, by means of suitable diffusion barriers, the reduction in the level of efficiency can be lessened by ca. 50%.

The present invention makes available a solar module, in particular a thin-film solar module, as well as a method for its production, wherein, by means of diffusion barriers for water molecules and dopant ions between the absorber zones of the solar cells and the adhesive layer, a reduction in the age-induced power loss can be achieved. The production of the diffusion barriers can be integrated simply and economically into the industrial series production of solar modules.

### LIST OF REFERENCE SIGNS

1 thin-film solar module
2 thin-film solar cell
3 first substrate
4 layer structure
5 rear electrode
6 absorber zone
7 buffer zone
8 front electrode
9 diffusion barrier
10 adhesive layer
11 second substrate
12 composite
13 radiation
14 current path
15 module surface
16 first layer trench
17 second layer trench
18 third layer trench
19 rear electrode layer
20 front electrode layer
21 semiconductor layer
22 barrier layer
23 buffer layer

1. A solar module comprising:
a laminated composite of two substrates bonded to one another by at least one adhesive layer,
serially connected solar cells between the two substrates, each solar cell comprising an absorber zone, made of a semiconducting material, between a front electrode arranged on a light-entry side of the absorber zone and a rear electrode, and
a diffusion barrier, differing from the front electrode, situated between the absorber zone and the adhesive layer, said diffusion barrier is being configured to inhibit diffusion of water molecules out of the adhesive layer into the absorber zone and/or diffusion of dopant ions out of the absorber zone into the adhesive layer.

2. The solar module according to claim 1, wherein the diffusion barrier includes at least one metal oxide layer.

3. The solar module according to claim 2, wherein the diffusion barrier includes an alternating sequence of at least one metal oxide layer and at least one metal nitride layer.

4. The solar module according to claim 3, wherein the diffusion barrier consists of an alternating sequence of at least one layer made of tin zinc oxide and at least one layer made of silicon nitride.

5. The solar module according to claim 1, wherein a layer thickness of the diffusion barrier is more than 50 nm.

6. The solar module according to claim 1, wherein the diffusion barrier is arranged between the front electrode and the adhesive layer.

7. The solar module according to claim 1, wherein the diffusion barrier is arranged between the front electrode and the absorber zone.

8. The solar module according to claim 1, further comprising:
a rear electrode layer with first layer trenches for forming the rear electrodes (5),
a semiconductor layer with second layer trenches for forming the absorber zones, and
a front electrode layer with third layer trenches for forming the front electrodes,
wherein the diffusion barriers of the solar cells are situated outside the third layer trenches.

9. A method for producing a solar module, comprising:
bonding two substrates to one another by at least one adhesive layer to form a laminated composite,
situating serially connected solar cells between the two substrates, each solar cell comprising an absorber zone, made of a semiconducting material, and
arranging the solar cells between a front electrode on a light-entry side of the absorber zone and a rear electrode,
arranging in each solar cell, a diffusion barrier differing from the front electrode between the absorber zone and the adhesive layer, said diffusion barrier being configured to inhibit diffusion of water molecules out of the adhesive layer into the absorber zone and/or diffusion of dopant ions out of the absorber zone into the adhesive layer.

10. The method according to claim 9, wherein a barrier layer for a formation of the diffusion barriers of the solar cells is produced by chemical or physical vapor deposition or magnetic field assisted cathode sputtering.

11. The method according to claim 10, wherein the barrier layer for the formation of the diffusion barriers of the solar cells is produced by deposition of at least one metal oxide layer.

12. The method according to claim 11, wherein the barrier layer for the formation of the diffusion barriers of the solar cells is produced by deposition of an alternating sequence of at least one metal oxide layer and at least one metal nitride layer.

13. The method according to claim 9, wherein
the rear electrodes are produced by forming first layer trenches in a rear electrode layer;
the absorber zones are produced by forming second layer trenches in a semiconductor layer;
the front electrodes are produced by forming third layer trenches in a front electrode layer, and
a barrier layer is deposited on the front electrode layer serving for a production of the front electrodes.

14. The method according to claim 9, wherein
the rear electrodes are produced by forming first layer trenches in a rear electrode layer;
the absorber zones are produced by forming second layer trenches in a semiconductor layer;
the front electrodes are produced by forming third layer trenches in a front electrode layer, and
a barrier layer is deposited on the front electrodes and third layer trenches.

15. A method comprising:
using a diffusion barrier in a solar module, the solar module comprising:
a laminated composite of two substrates bonded to one another by at least one adhesive layer, and
serially connected solar cells situated between the two substrates, each solar cell comprising an absorber zone, made of a semiconducting material, between a front electrode arranged on a light-entry side of the absorber zone and a rear electrode,
wherein the diffusion barrier is different from the front electrode and is situated between the absorber zone and the adhesive layer, and the diffusion barrier is configured for inhibiting diffusion of water molecules out of the adhesive layer into the absorber zone and/or diffusion of dopant ions out of the absorber zone into the adhesive layer.

16. The solar module according to claim 5, wherein the layer thickness of the diffusion barrier is in the range from more than 50 nm to 200 nm.

17. The solar module according to claim 16, wherein the layer thickness of the diffusion barrier is in the range from 75 nm to 100 nm.
